(19) United States
(12) Patent Application Publication
(10) Pub. No.: US 2024/0371936 A1
(43) Pub. Date: Nov. 7, 2024

(54) SEMICONDUCTOR APPARATUS AND METHOD OF MANUFACTURING SEMICONDUCTOR APPARATUS

(71) Applicant: Asahi Kasei Microdevices Corporation, Tokyo (JP)

(72) Inventor: Shuntaro FUJII, Tokyo (JP)

(73) Assignee: Asahi Kasei Microdevices Corporation, Tokyo (JP)

(21) Appl. No.: 18/592,519

(22) Filed: Mar. 1, 2024

(30) Foreign Application Priority Data
May 1, 2023 (JP) 2023-075736

(51) Int. Cl. H01L 29/08; H01L 21/265; H01L 21/324; H01L 29/06; H01L 29/66; H01L 29/786

(52) U.S. Cl. CPC H01L 29/0847; H01L 21/26513; H01L 21/324; H01L 29/0603; H01L 29/66568; H01L 29/78696

(57) ABSTRACT

A semiconductor apparatus includes a gate insulating film, a well region of a first conductivity type located on a surface layer of a semiconductor substrate, a source region of a second conductivity type and a drain region of the second conductivity type located on a surface layer of the well region, a first region of the second conductivity type, and a second region of the first conductivity type. The first region is located between the source region and the drain region and is buried in the well region. The second region is located between the first region and the gate insulating film. A burying depth of the first region in the well region from the surface of the semiconductor substrate is 50 nm or more.

### CROSS-REFERENCE TO RELATED APPLICATION

The present application claims priority to Japanese Patent Application No. 2023-075736 filed on May 1, 2023, the entire contents of which are incorporated herein by reference.

### TECHNICAL FIELD

The present disclosure relates to a semiconductor apparatus and a method of manufacturing a semiconductor apparatus.

### BACKGROUND

To improve the performance of analog circuits, it is effective to reduce the 1/f noise of metal-oxide-semiconductor (MOS) transistors placed in the circuit. One cause of 1/f noise is that carriers are trapped in the interface between the gate insulating film and the semiconductor substrate.

A known way of addressing 1/f noise is to use a buried channel transistor. A buried channel transistor is a transistor configured so that the region where the channel is formed is buried in the semiconductor substrate. In such a buried channel transistor, carriers are less likely to be trapped in the interface between the gate insulating film and the semiconductor substrate. The 1/f noise is therefore reduced with the buried channel transistor as compared to a surface channel transistor. If the region where the channel is formed is configured to be deeply buried in the semiconductor substrate, however, a short-channel effect increases. To address this, a buried channel transistor in which the depth of the region where the channel is formed is 0.05 μm or less is known, as in Patent Literature (PTL) 1.

### CITATION LIST

### Patent Literature

PTL 1: U.S. Pat. No. 5,767,557

### SUMMARY

To reduce the 1/f noise in a buried channel transistor, it is desirable to bury the region where the channel is formed deep into the semiconductor substrate. If the region where the channel is formed is deeply buried in the semiconductor substrate in a conventional transistor, however, the short-channel effect increases.

It would be helpful to provide a semiconductor apparatus and a method for manufacturing a semiconductor apparatus in which an increase in the short-channel effect is suppressed while 1/f noise is reduced.

[1] A semiconductor apparatus according to an embodiment of the present disclosure includes:
a gate insulating film;
a well region of a first conductivity type located on a surface layer of a semiconductor substrate;
a source region of a second conductivity type and a drain region of the second conductivity type located on a surface layer of the well region;
a first region of the second conductivity type located between the source region and the drain region and buried in the well region; and
a second region of the first conductivity type located between the first region and the gate insulating film, wherein a burying depth of the first region in the well region from a surface of the semiconductor substrate is 50 nm or more.

[2] In an embodiment of the present disclosure, in [1],
the well region contains an impurity of the first conductivity type,
the first region and the second region contain an identical type of impurity of the second conductivity type,
a concentration of the impurity of the second conductivity type contained in the first region is higher than a concentration of the impurity of the first conductivity type contained in the well region,
a concentration of the impurity of the second conductivity type contained in the second region is lower than the concentration of the impurity of the first conductivity type contained in the well region, and
the concentration of the impurity of the first conductivity type is in a range of 1×10¹⁶ cm⁻³ or more to 1×10¹⁸ cm⁻³ or less.

[3] In an embodiment of the present disclosure, in [2], the impurity of the second conductivity type is indium.

[4] In an embodiment of the present disclosure, in [2] or [3], the second region is buried in the well region together with the first region.

[5] In an embodiment of the present disclosure, in any one of [2] to [4], a burying depth of the second region in the well region from the surface of the semiconductor substrate is 1 nm or more and 50 nm or less.

[6] In an embodiment of the present disclosure, in [1],
the second region is a silicon thin film, and
the second region is located above the semiconductor substrate.

[7] In an embodiment of the present disclosure, in [6], the first region contains boron as an impurity of the second conductivity type.

[8] In an embodiment of the present disclosure, in [6] or [7], a thickness of the second region is 10 nm or more and 50 nm or less.

[9] In an embodiment of the present disclosure, in any one of [1] to [8], an interface state density between the gate insulating film and the semiconductor substrate is 1.0×10¹⁰ cm⁻² or less.

In an embodiment of the present disclosure, in any one of [1] to [9], the interface state density between the gate insulating film and the semiconductor substrate is 1.0×10⁹ cm⁻² or more and 1.0×10¹⁰ cm⁻² or less.

As an embodiment of the present disclosure, a method of manufacturing the semiconductor apparatus according to any one of [2] to [5] includes:
performing counter ion implantation of impurity ions of the second conductivity type in the semiconductor substrate so that the concentration of the impurity of the second conductivity type on the gate insulating film side in the well region is lower than the concentration of the impurity of the first conductivity type in the well region, wherein
the impurity of the second conductivity type exhibits a retrograde distribution.

In an embodiment of the present disclosure, in [11], the method further includes
performing high temperature lamp annealing after forming an insulating film that becomes the gate insulating film and a polysilicon film that becomes a gate electrode, wherein
the high temperature lamp annealing is performed under conditions of a temperature of 965° C. or more and 1125° C. or less and a time of 15 seconds or more and 60 seconds or less.

As an embodiment of the present disclosure, a method of manufacturing the semiconductor apparatus according to any one of [6] to [8] includes:
performing counter ion implantation of impurity ions of the second conductivity type in the semiconductor substrate;
forming a silicon thin film on the semiconductor substrate by epitaxial growth; and
performing ion implantation of impurity ions of the first conductivity type in the silicon thin film.

In an embodiment of the present disclosure, in [13], the method further includes
performing high temperature lamp annealing after forming an insulating film that becomes the gate insulating film and a polysilicon film that becomes a gate electrode, wherein
the high temperature lamp annealing is performed under conditions of a temperature of 965° C. or more and 1050° C. or less and a time of 15 seconds or more and 30 seconds or less.

As an embodiment of the present disclosure, a method of manufacturing the semiconductor apparatus according to any one of [6] to [8] includes:
performing counter ion implantation of impurity ions of the second conductivity type in the semiconductor substrate; and
forming a silicon thin film doped with an impurity of the first conductivity type on the semiconductor substrate by epitaxial growth.

In an embodiment of the present disclosure, in [15], the method further includes
performing high temperature lamp annealing after forming an insulating film that becomes the gate insulating film and a polysilicon film that becomes a gate electrode, wherein
the high temperature lamp annealing is performed under conditions of a temperature of 965° C. or more and 1050° C. or less and a time of 15 seconds or more and 30 seconds or less.

According to the present disclosure, a semiconductor apparatus and a method for manufacturing a semiconductor apparatus in which an increase in the short-channel effect is suppressed while 1/f noise is reduced can be provided.

### BRIEF DESCRIPTION OF THE DRAWINGS

In the accompanying drawings:

FIG. 1 is a cross-sectional diagram illustrating a schematic configuration of a semiconductor apparatus according to a first embodiment of the present disclosure;

FIG. 2 is a cross-sectional diagram illustrating a method of manufacturing the semiconductor apparatus illustrated in FIG. 1;

FIG. 3 is a cross-sectional diagram illustrating a method of manufacturing the semiconductor apparatus illustrated in FIG. 1;

FIG. 4 is a cross-sectional diagram illustrating a method of manufacturing the semiconductor apparatus illustrated in FIG. 1;

FIG. 5 is a cross-sectional diagram illustrating a method of manufacturing the semiconductor apparatus illustrated in FIG. 1;

FIG. 6 is a cross-sectional diagram illustrating a method of manufacturing the semiconductor apparatus illustrated in FIG. 1;

FIG. 7 is a cross-sectional diagram illustrating a method of manufacturing the semiconductor apparatus illustrated in FIG. 1;

FIG. 8 is a cross-sectional diagram illustrating a method of manufacturing the semiconductor apparatus illustrated in FIG. 1;

FIG. 9 is a cross-sectional diagram illustrating a method of manufacturing the semiconductor apparatus illustrated in FIG. 1;

FIG. 10 is a cross-sectional diagram illustrating a method of manufacturing the semiconductor apparatus illustrated in FIG. 1;

FIG. 11 is a cross-sectional diagram illustrating a method of manufacturing the semiconductor apparatus illustrated in FIG. 1;

FIG. 12 is a diagram illustrating the results of simulating impurity distributions;

FIG. 13 is a diagram illustrating the results of actual measurement of drain current-gate voltage characteristics (I_{d}-V_{g} characteristics) of a transistor;

FIG. 14 is a diagram illustrating the results of actual measurement of the interface state density (Nss) between a gate insulating film and a semiconductor substrate;

FIG. 15 is a diagram illustrating the results of simulating valence bands;

FIG. 16 is a diagram illustrating the results of actual measurement of 1/f noise;

FIG. 17 is a cross-sectional diagram illustrating a schematic configuration of a semiconductor apparatus according to a second embodiment of the present disclosure;

FIG. 18 is a cross-sectional diagram illustrating a method of manufacturing the semiconductor apparatus illustrated in FIG. 17;

FIG. 19 is a cross-sectional diagram illustrating a method of manufacturing the semiconductor apparatus illustrated in FIG. 17;

FIG. 20 is a cross-sectional diagram illustrating a method of manufacturing the semiconductor apparatus illustrated in FIG. 17;

FIG. 21 is a diagram illustrating the results of simulating an impurity distribution according to a Comparative Example;

FIG. 22 is a diagram illustrating the results of simulating an impurity distribution according to an Example;

FIG. 23 is a diagram illustrating the results of simulation of drain current-gate voltage characteristics (I_{d}-V_{g} characteristics); and

FIG. 24 is a diagram illustrating the results of simulating valence bands.

### DETAILED DESCRIPTION

A semiconductor apparatus and a method of manufacturing a semiconductor apparatus according to embodiments of the present disclosure are described below with reference to the drawings. In each drawing, the same or similar constituent elements are indicated with the same reference sign. For convenience of explanation, “above” refers to the gate electrode side in the semiconductor apparatus, and “below” refers to the opposite side.

### First Embodiment

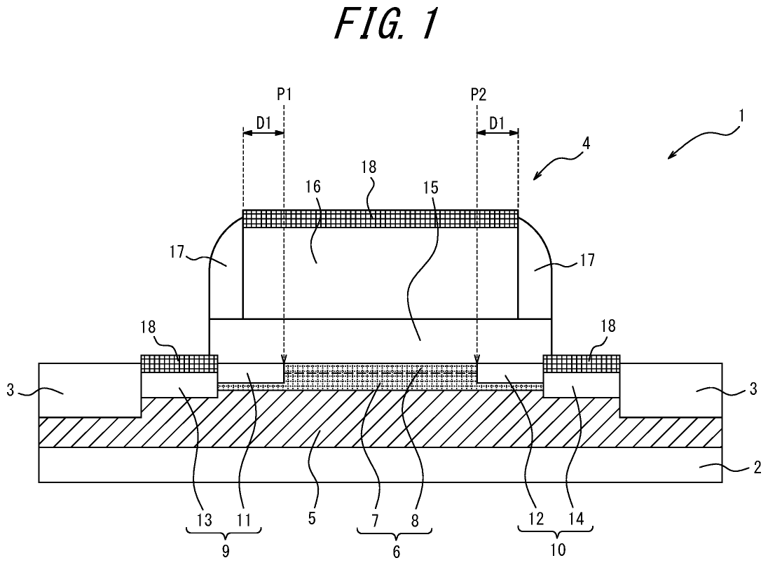

As illustrated in FIG. 1, a semiconductor apparatus 1 according to a first embodiment of the present disclosure includes a semiconductor substrate 2, an element separation layer 3, and a transistor 4.

The semiconductor substrate 2 is, for example, a single crystal silicon substrate. The semiconductor substrate 2 is n-type or p-type. Semiconductor elements are located on the surface layer of the semiconductor substrate 2.

The element separation layer 3 separates the semiconductor elements located on the surface layer of the semiconductor substrate 2. In FIG. 1, the element separation layer 3 separates the transistor 4, which is a semiconductor element.

The transistor 4 is located on the surface layer of the semiconductor substrate 2. The transistor 4 is a MOSFET (Metal-Oxide-Semiconductor Field Effect Transistor). The transistor 4 is a p-type buried channel transistor. The transistor 4 may, however, instead be an n-type buried channel transistor.

In the present embodiment, the first conductivity type is n-type. The second conductivity type is p-type. In a case in which the transistor 4 is an n-type buried channel transistor, however, the first conductivity type may be p-type and the second conductivity type may be n-type.

The transistor 4 includes a well region 5, a buried region 6, a source region 9, a drain region 10, a gate insulating film 15, a gate electrode 16, a sidewall 17, and a silicide layer 18.

The well region 5 is located on the surface layer of the semiconductor substrate 2. The well region 5 is n-type. The well region 5 contains an n-type impurity. The well region 5 contains, for example, phosphorus.

The buried region 6 is located between the source region 9 and the drain region 10. The buried region 6 is buried in the well region 5. The depth of the buried region 6 from the surface of the semiconductor substrate 2 is 50 nm or more. The buried region 6 includes a first region 7 and a second region 8.

The first region 7 is located farther from the gate insulating film 15 than the second region 8. The burying depth of the first region 7 in the well region 5 from the surface of the semiconductor substrate 2 is, for example, 50 nm or more. The burying depth of the first region 7 in the well region 5 from the surface of the semiconductor substrate 2 may be 50 nm or more and 90 nm or less. The second region 8 is located between the first region 7 and the gate insulating film 15. In the present embodiment, the second region 8 is buried in the well region 5 together with the first region 7. The burying depth of the second region 8 in the well region 5 may be selected according to the burying depth of the first region 7 in the well region 5. The burying depth of the second region 8 in the well region 5 from the surface of the semiconductor substrate 2 is, for example, 1 nm or more and 50 nm or less.

The first region 7 is p-type. The second region 8 is n-type. The first region 7 and second region 8 contain the same type of p-type impurity. As described below, the first region 7 and second region 8 are formed simultaneously by counter ion implantation of p-type impurity ions into the well region 5. These p-type impurity ions are, for example, indium ion (In). By the counter ion implantation using indium ions (In), described below, the concentration of indium, which is a p-type impurity, contained in the second region 8 becomes lower than the concentration of phosphorus, which is an n-type impurity, in the well region 5. On the other hand, the concentration of indium, which is a p-type impurity, contained in the first region 7 becomes higher than the concentration of phosphorus, which is an n-type impurity, in the well region 5. This configuration makes the first region 7 p-type and the second region 8 n-type. To enhance the degree of burying in the channel, the impurity concentration in the second region is set to 1×10¹⁶ cm⁻³ or more. However, if the impurity concentration increases to more than 1×10¹⁸ cm⁻³, the threshold voltage (Vₜₕ) variation becomes more pronounced. A range of 1×10¹⁶ cm⁻³ or more to 1×10¹⁸ cm⁻³ or less is therefore preferable.

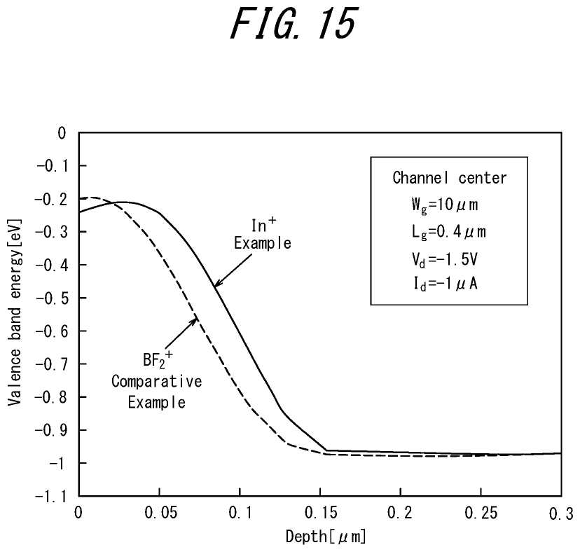

A channel is formed in the buried region 6 when the transistor 4 is in the on state. The location of the second region 8 between the first region 7 and the gate insulating film 15 can increase the degree to which the channel is buried in the buried region 6, as described below with reference to FIG. 15.

The source region 9 and the drain region 10 are each located on the surface layer of the well region 5. The source region 9 and drain region 10 are isolated from each other. The source region 9 is p-type. The source region 9 includes a p-type extension region 11 and a p-type contact region 13. The drain region 10 is p-type. The drain region 10 includes a p-type extension region 12 and a p-type contact region 14.

The extension regions 11, 12 are respectively formed in alignment with the gate electrode 16. In the direction from the source region 9 to the drain region 10, a junction position P1 between the extension region 11 and the buried region 6 is located inward by a length DI from the edge of the gate electrode 16. Identically or similarly, in the direction from the source region 9 to the drain region 10, a junction position P2 between the extension region 12 and the buried region 6 is located inward by a length DI from the edge of the gate electrode 16. The length DI is, for example, 5 nm or more and 100 nm or less.

The extension regions 11, 12 are located in a shallower region than the respective contact regions 13, 14. The location of the extension regions 11, 12 in a shallower region reduces the short-channel effect of the transistor 4.

The contact region 13 is also referred to as the deep source region. The contact region 14 is also referred to as the deep drain region. The contact regions 13, 14 are respectively formed in alignment with the sidewall 17. The concentration of the p-type impurity in each of the contact regions 13, 14 is higher than the concentration of the p-type impurity in each of the extension regions 11, 12. Each of the contact regions 13, 14 is connected to wiring via the silicide layer 18. By the increase in the concentration of the p-type impurity in each of the contact regions 13, 14, the contact resistance with the wiring can be reduced.

The gate insulating film 15 is located on the semiconductor substrate 2. The gate insulating film 15 is, for example, a silicon oxide (SiO₂) film. The thickness of the gate insulating film 15 is, for example, 4 nm to 20 nm.

The interface state density between the gate insulating film 15 and the semiconductor substrate 2 may be 1.0×10¹⁰ cm⁻² or less, or may be 1.0×10⁹ cm⁻² or more and 1.0×10¹⁰ cm⁻² or less. The interface state density between the gate insulating film 15 and the semiconductor substrate 2 can be set to 1.0×10¹⁰ cm⁻² or less by performing high temperature lamp annealing, described below.

The gate electrode 16 is located above the gate insulating film 15. The gate electrode 16 is, for example, an n′ polysilicon film. The gate electrode 16 may, however, be a p polysilicon film. The thickness of the gate electrode 16 is, for example, 100 nm to 400 nm.

The sidewall 17 is located above the gate insulating film 15. The sidewall 17 is formed on the side of the gate electrode 16.

The silicide layer 18 is formed above each of the contact regions 13, 14 and the gate electrode 16. The silicide layer 18 is formed in alignment with the sidewall 17. The silicide layer 18 is formed by, for example, cobalt silicide (CoSi₂), titanium silicide (TiSi₂), or nickel silicide (NiSi₂).

### <Method of Manufacturing a Semiconductor Apparatus>

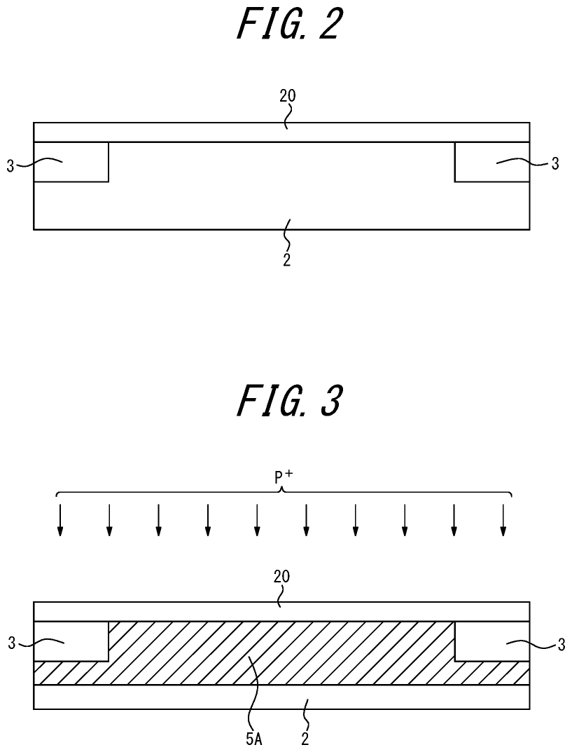

Next, a method of manufacturing the semiconductor apparatus 1 illustrated in FIG. 1 will be described with reference to FIGS. 2 to 11. By modifying the method of manufacturing described below as appropriate, a semiconductor apparatus 1 provided with an n-type buried channel transistor instead of or in addition to the transistor 4 may be manufactured.

First, the semiconductor substrate 2 is prepared. Next, as illustrated in FIG. 2, the element separation layer 3 is formed on the surface layer of the semiconductor substrate 2. By formation of the element separation layer 3, the semiconductor elements formed on the semiconductor substrate 2 are separated. The element separation layer 3 is formed by STI (Shallow Trench Isolation) or LOCOS (Local Oxidation of Silicon), for example. A through film 20 is subsequently formed on the semiconductor substrate 2. The through film 20 is, for example, a silicon oxide (SiO₂) film. The thickness of the through film 20 is, for example, 5 nm to 40 nm.

Next, phosphorus ions (P), which are n-type impurity ions, are selectively implanted in the surface layer of the semiconductor substrate 2 through the through film 20, as illustrated in FIG. 3. The implantation of phosphorus ions (P) is, for example, performed under the conditions of an acceleration voltage of 120 keV to 160 keV and a dose of 3×10¹² cm⁻² to 1×10¹³ cm⁻². A well region 5A is formed by the implantation of phosphorus ions (P).

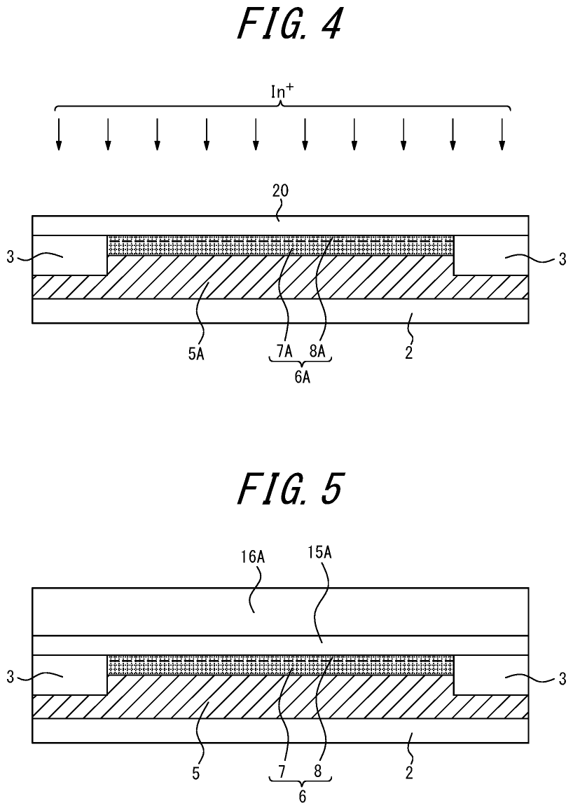

Next, counter ion implantation is performed as illustrated in FIG. 4. In the present embodiment, indium ions (In), which are p-type impurity ions, are selectively implanted in the well region 5A through the through film 20. During counter ion implantation, indium ions (In) are implanted in the well region 5A so that the indium concentration on the gate insulating film 15 side in the well region 5 illustrated in FIG. 1 is lower than the phosphorus concentration in the well region 5. When indium ions (In) are implanted in the well region 5A, the concentration distribution of indium in the well region 5A becomes a retrograde distribution. The retrograde distribution is a concentration distribution in which the concentration changes as the position changes along one direction. Such counter ion implantation is used to form a buried region 6A. The buried region 6A includes a second region 8A, which later becomes the second region 8, and a first region 7A, which later becomes the first region 7.

It is known that in counter ion implantation, as the dose of indium ions (In⁺) increases, a kink appears in the drain current-gate voltage characteristics (I_{d}-V_{g} characteristics) of the transistor due to indium deactivation (I.C. Kizilyalli et al, IEEE Electron Device Letters, vol. 17 (1996), p. 46). Therefore, during counter ion implantation according to the present embodiment, indium ions (In⁺) are, for example, implanted at an acceleration voltage of 80 keV to 120 keV and a dose of 1×10¹² cm⁻² to 6×10¹² cm⁻². This configuration can suppress the appearance of a kink in the drain current-gate voltage characteristics of the transistor 4.

After counter ion implantation is performed, activation annealing is performed. The activation annealing activates the impurity ions in the well region 5A, the second region 8A, and the first region 7A. The activation of the impurity ions forms the n-type well region 5, the p-type first region 7, and the n-type second region 8, as illustrated in FIG. 5.

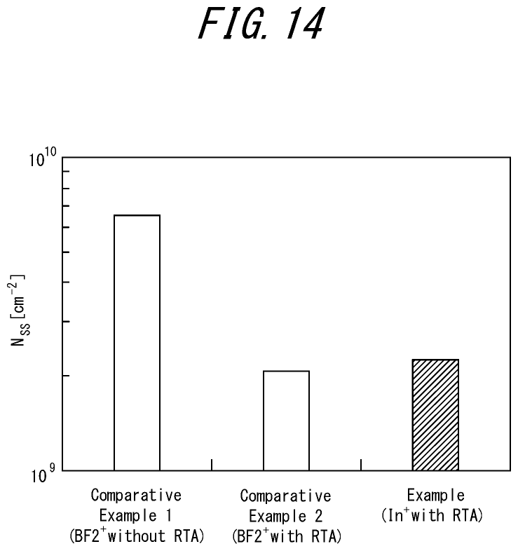

Next, after the through film 20 is removed, an insulating film 15A and a polysilicon film 16A are formed, as illustrated in FIG. 5. The insulating film 15A is, for example, silicon oxide (SiO₂) formed by thermal or plasma oxidation. The thickness of the insulating film 15A is, for example, 4 nm to 20 nm. The polysilicon film 16A is formed by, for example, depositing a polysilicon thin film. The thickness of the polysilicon film 16A is, for example, 100 nm to 400 nm. After the insulating film 15A and the polysilicon film 16A are formed, high temperature lamp annealing is performed. The high temperature lamp annealing is performed, for example, by the RTA (Rapid Thermal Anneal) method. The high temperature lamp annealing is performed under conditions of a temperature of 965° C. or more and 1125° C. or less and a time of 15 seconds or more and 60 seconds or less. The high temperature lamp annealing reduces the interface state density of the transistor 4, as described below with reference to FIG. 14. The reduction of the interface state density can reduce the 1/f noise in the transistor 4.

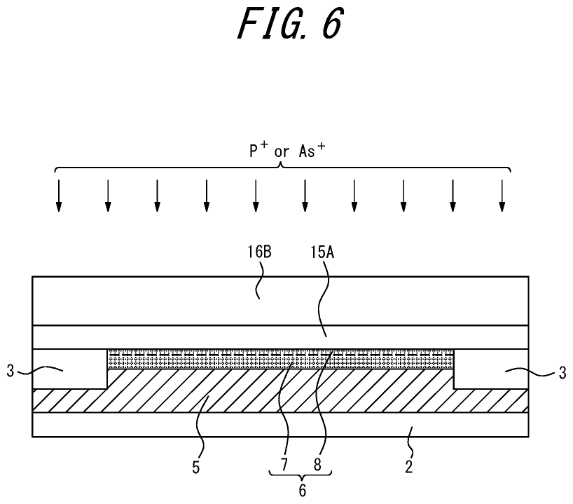

Next, phosphorus ions (P⁺) or arsenic ions (As⁺) are implanted into the polysilicon film 16A to form an electrode layer 16B, as illustrated in FIG. 6. The electrode layer 16B is an n′ polysilicon film. In a case in which the threshold voltage of the transistor 4 is to be lowered, an electrode layer 16B that becomes a p polysilicon film may be formed by implanting boron ions (B) in the polysilicon film 16A.

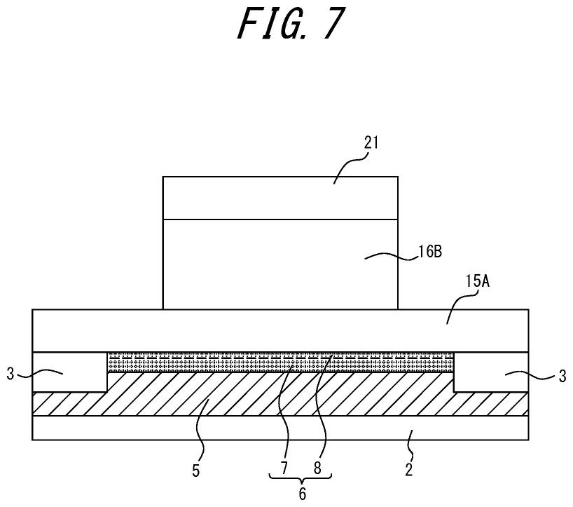

Next, after a hard mask 21 is deposited on the surface of the electrode layer 16B, the hard mask 21 and the electrode layer 16B are etched, as illustrated in FIG. 7. The hard mask 21 is formed by, for example, the CVD (Chemical Vapor Deposition) method. The thickness of the hard mask 21 is, for example, 50 nm.

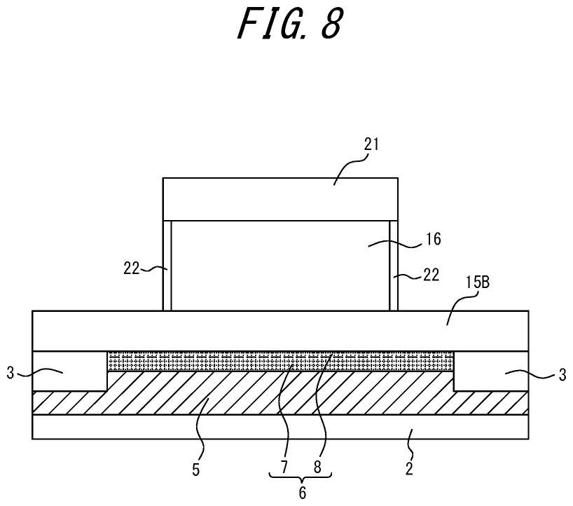

Next, re-oxidation is performed to form the gate electrode 16 and an insulating film 15B, as illustrated in FIG. 8. Re-oxidation is performed under temperature conditions of 800° C. to 900° C., for example. The re-oxidation causes impurities implanted into the electrode layer 16B illustrated in FIG. 7 to diffuse to the interface between the electrode layer 16B and the insulating film 15A. Such diffusion forms the gate electrode 16 illustrated in FIG. 8. In addition, an oxide film 22 is formed on the side of the gate electrode 16 by re-oxidation.

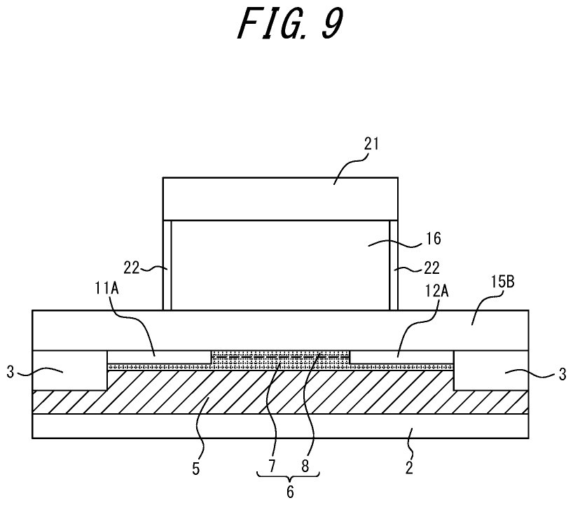

Next, extension ion implantation is performed to form implantation regions 11A, 12A, as illustrated in FIG. 9. In extension ion implantation, boron ions (B⁺) or boron bifluoride ions (BF₂⁺) are selectively implanted. The extension ion implantation is, for example, performed under the conditions of an acceleration voltage of 3 keV to 15 keV and a dose of 1×10¹³ cm⁻² to 1×10¹⁵ cm⁻². The tilt angle during extension ion implantation is adjusted so that the respective edges of the extension regions 11, 12 illustrated in FIG. 1 are located inside the edge of the gate electrode 16.

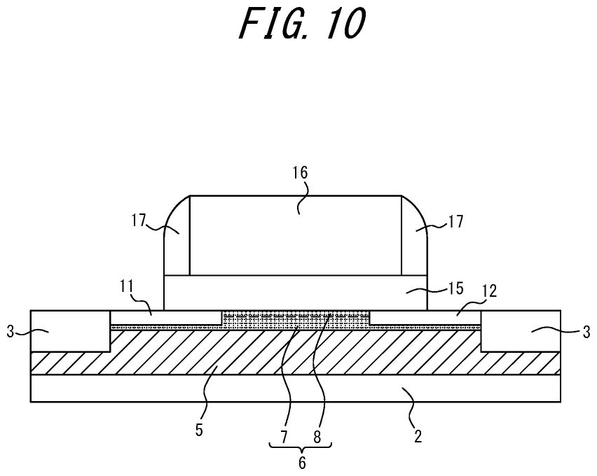

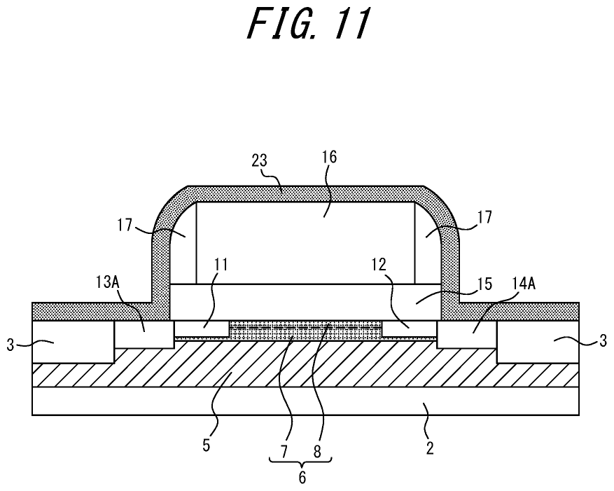

After extension ion implantation is performed, activation annealing is performed. The activation annealing activates the impurity ions in the implantation regions 11A, 12A. The activation of the impurity ions forms the extension regions 11, 12, as illustrated in FIG. 10.

Next, the sidewall 17 is formed as illustrated in FIG. 10. The sidewall 17 is formed by, for example, forming an insulating film by the CVD method and anisotropic etching. This insulating film is, for example, silicon oxide or silicon nitride. The sidewall 17 is formed in alignment with the gate electrode 16. At this time, the hard mask 21 illustrated in FIG. 9 is etched. The insulating film 15B is also etched to form the gate insulating film 15 illustrated in FIG. 10.

Next, as illustrated in FIG. 11, a through film 23 is formed on the entire surface layer of the semiconductor substrate 2, including the gate insulating film 15, the gate electrode 16, and the sidewall 17. The through film 23 is, for example, silicon oxide (SiO₂). The through film 23 is formed by, for example, the CVD method. The thickness of the through film 23 is, for example, 10 nm. Once the through film 23 is formed, the gate electrode 16 and sidewall 17 are masked, and contact impurity ions are selectively implanted in the surface layer of the semiconductor substrate 2. The contact impurity ions are, for example, boron ions (B⁺) or boron bifluoride ions (BF₂⁺). The contact impurity ion implantation is, for example, performed under the conditions of an acceleration voltage of 10 keV to 40 keV and a dose of 1×10¹⁵ cm⁻² to 5×10¹⁵ cm⁻². The contact impurity ions are implanted to form implantation regions 13A, 14A, as illustrated in FIG. 11.

After the implantation regions 13A, 14A are formed, activation annealing is performed. Performance of the activation annealing forms the contact regions 13, 14 illustrated in FIG. 1. Subsequently, the silicide layer 18 illustrated in FIG. 1 is formed. In forming the silicide layer 18, first, the through film 23 illustrated in FIG. 11 is removed by wet etching or the like to expose the surfaces of the contact regions 13, 14 and the gate electrode 16. Next, after a metal film is produced on the surfaces of the exposed contact regions 13, 14 and gate electrode 16, an annealing process is performed to form the silicide layer 18. The unreacted metal film is then selectively removed by chemical treatment. Subsequently, post-processing to form the wiring layer is performed, thereby forming the semiconductor apparatus 1 as illustrated in FIG. 1.

### <Result 1>

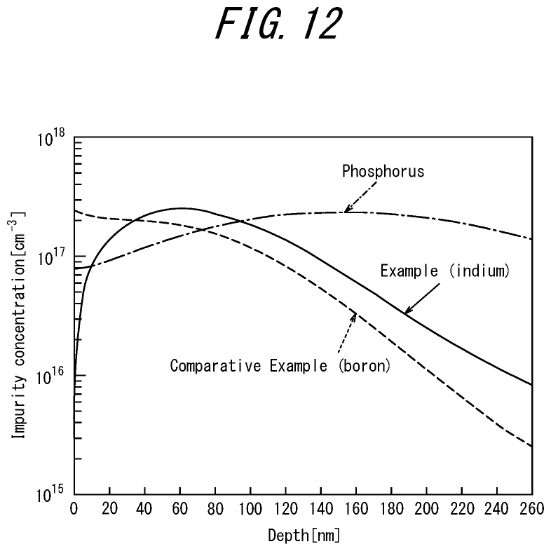

FIG. 12 is a diagram illustrating the results of simulating impurity distributions. In FIG. 12, the horizontal axis indicates the depth [nm] in the semiconductor substrate. The 0 [nm] on the horizontal axis corresponds to the interface between the gate oxide film and the semiconductor substrate. The vertical axis indicates the impurity concentration [cm⁻³].

The dashed dotted line indicates the phosphorus concentration in the semiconductor substrate in a case in which phosphorus ions (P⁺) are implanted under the conditions described above with reference to FIG. 3.

The solid line indicates an Example. In other words, the solid line indicates the indium concentration in the semiconductor substrate in a case in which counter ion implantation of indium ions (In⁺) was performed under the conditions described above with reference to FIG. 4. The condition on the acceleration voltage for implanting indium ions (In⁺) was 100 keV.

The dashed line indicates the concentration of boron in the semiconductor substrate in a case in which counter ion implantation of boron bifluoride ions (BF₂⁺) was performed as a Comparative Example. The condition on the acceleration voltage for implanting boron bifluoride ions (BF₂⁺) was 60 keV.

As can be seen from the dashed line, the boron concentration reaches a maximum near the interface between the gate oxide film and the semiconductor substrate. The boron concentration decreases with depth in the semiconductor substrate.

A comparison between the dashed line and the dashed dotted line reveals that the boron concentration is higher than the phosphorus concentration in a range in which the depth in the semiconductor substrate is 0 nm to 70 nm. The boron concentration falls below the phosphorus concentration in a range in which the depth in the semiconductor substrate is deeper than 70 nm. In other words, when counter ion implantation of boron bifluoride ions (BF₂⁺) was performed, the semiconductor substrate becomes p-type at depths in a range of 0 nm to 70 nm. The semiconductor substrate becomes n-type at depths in a range deeper than 70 nm.

As can be seen from the solid line, the indium concentration increases with depth in the semiconductor substrate in a range in which the depth in the semiconductor substrate is 0 nm to 60 nm. The indium concentration reaches a maximum at a depth of 60 nm in the semiconductor substrate. The indium concentration decreases with depth in the semiconductor substrate in a range in which the depth in the semiconductor substrate is greater than 60 nm.

A comparison between the solid line and the dashed dotted line reveals that the indium concentration is lower than the phosphorus concentration in a range in which the depth in the semiconductor substrate is 0 nm to 10 nm. The indium concentration is higher than the phosphorus concentration in a range in which the depth in the semiconductor substrate is 10 nm to 90 nm. The indium concentration is lower than the phosphorus concentration in a range in which the depth in the semiconductor substrate is greater than 90 nm. In other words, in a case in which counter ion implantation of indium ions (In⁺) was performed, the semiconductor substrate becomes n-type at depths in a range of 0 nm to 10 nm. The semiconductor substrate becomes p-type at depths in a range of 10 nm to 90 nm. The semiconductor substrate becomes n-type at depths in a range deeper than 90 nm. With this configuration, the p-type first region 7 and the n-type second region 8, as illustrated in FIG. 1, can be formed simultaneously by counter ion implantation using indium ions (In⁺).

### <Result 2>

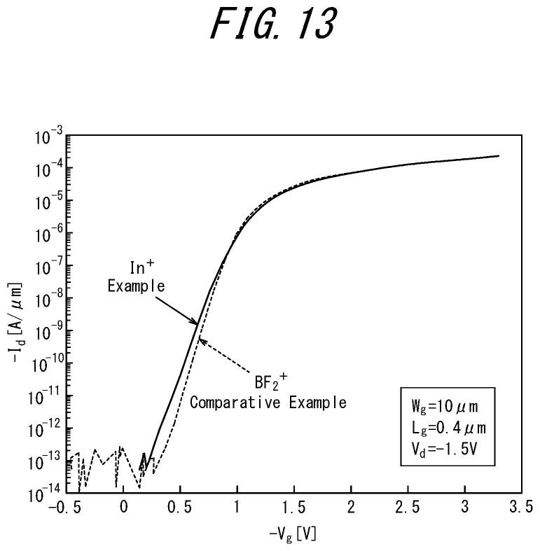

FIG. 13 is a diagram illustrating the results of actual measurement of drain current-gate voltage characteristics (I_{d}-V_{g} characteristics) of a transistor. The gate width (W_{g}) of the transistor used for the actual measurement was 10 μm, and the gate length (L_{g}) of the transistor was 0.4 μm. The drain voltage (V_{d}) was set to −1.5 V for the actual measurement.

In FIG. 13, the horizontal axis indicates the gate voltage (−V_{g} [V]). The vertical axis indicates the drain current (−I_{d}[A/μm]).

The solid line indicates an Example. That is, the solid line indicates the drain current-gate voltage characteristics of a transistor 4 formed by counter ion implantation of indium ions (In⁺).

The dashed line indicates the drain current-gate voltage characteristics of a transistor formed by counter ion implantation of boron bifluoride ions (BF₂⁺) as a Comparative Example.

The transistor 4 in the Example had slightly worse subthreshold characteristics than the transistor in the Comparative Example. However, the Example and Comparative Example exhibited nearly identical I_{d}-V_{g} characteristics. In addition, by the dose of indium ions (In⁺) being set to 6×10¹² cm⁻² or less, the transistor 4 in the Example was able to suppress the appearance of kinks in the I_{d}-V_{g} characteristics, as can be seen from the solid line.

### <Result 3>

FIG. 14 is a diagram illustrating the results of actual measurement of the interface state density (Nss) between a gate insulating film and a semiconductor substrate.

Comparative Example 1 is a case in which counter ion implantation of boron bifluoride ions (BF₂⁺) was performed, but high temperature lamp annealing by the RTA method was not performed.

Comparative Example 2 is a case in which counter ion implantation of boron bifluoride ions (BF₂⁺) and high temperature lamp annealing by the RTA method were performed.

The Example is a case in which counter ion implantation of indium ions (In⁺) and high temperature lamp annealing by the RTA method were performed.

In Comparative Example 1, the interface state density was 6.5×10⁹ cm⁻². In Comparative Example 2 and the Example, the interface state density was 2.1×10⁹ cm⁻². These results indicate that the interface state density can be reduced from 6.5×10⁹ cm⁻² to 2.1×10⁹ cm⁻² by performing high temperature lamp annealing after forming the polysilicon film 16A that becomes the gate electrode illustrated in FIG. 5. It can also be seen from Comparative Example 2 and the Example that the interface state density is independent of the type of impurity in the counter ion implantation, namely boron bifluoride ions (BF₂⁺) or indium ions (In⁺).

### <Result 4>

FIG. 15 is a diagram illustrating the results of simulating valence bands. The horizontal axis indicates the depth [μm] in the semiconductor substrate. The 0 [μm] on the horizontal axis corresponds to the interface between the gate oxide film and the semiconductor substrate. The vertical axis indicates the valence band energy [eV].

In this simulation, the gate width of the transistor (W_{g}) was set to 10 μm and the gate length of the transistor (L_{g}) was set to 0.4 μm in both the Example and the Comparative Example. The drain voltage (V_{d}) of the transistor was set to −1.5 V and the drain current (I_{d}) of the transistor was set to −1 μA. FIG. 15 illustrates the valence band energy in the center of the channel formed between the source region and the drain region of the transistor.

The solid line indicates the Example. In other words, the solid line indicates the valence band energy of the channel of the transistor 4 formed by counter ion implantation of indium ions (In⁺). In the Example, the burying depth of the first region 7 in the well region 5 from the surface of the semiconductor substrate 2 was 50 nm or more.

The dashed line indicates the valence band energy of the channel of a transistor formed by counter ion implantation of boron bifluoride ions (BF₂⁺) as the Comparative Example. In the Comparative Example, a p-type buried region is formed by counter ion implantation of boron bifluoride ions (BF₂⁺). In other words, in the transistor according to the Comparative Example, the entire buried region 6 illustrated in FIG. 1 is p-type. In the Comparative Example, the burying depth of this p-type buried region in the n-type well region from the surface of the semiconductor substrate was 50 nm or more.

As can be seen from the dashed line, the peak of the valence band energy in the Comparative Example was near a depth of 0 μm in the semiconductor substrate, i.e., near the interface. It can be seen from this result that when the drain current reaches approximately −1 μA in the Comparative Example, the channel ends up flowing through the interface between the gate insulating film and the p-type buried region. In other words, despite being a buried channel transistor, the transistor according to the Comparative Example behaves like a surface channel transistor when the drain current becomes approximately −1 μA. Thus, in the transistor according to the Comparative Example, when the drain current becomes approximately −1 μA, the channel ends up flowing through the interface between the gate insulating film and the p-type buried region, resulting in a large 1/f noise.

As can be seen from the solid line, the peak of the valence band energy in the Example was near a depth of 0.03 μm in the semiconductor substrate 2. In other words, in the Example, a channel is formed near a depth of 0.03 μm in the semiconductor substrate 2 even when the drain current becomes approximately −1 μA. That is, unlike the Comparative Example, the channel is buried in the semiconductor substrate in the transistor 4 according to the Example even when the drain current becomes approximately −1 μA. Since the channel is thus buried in the semiconductor substrate 2 in the transistor 4 according to the Example even when the drain current becomes approximately −1 μA, the 1/f noise can be reduced.

In this way, the degree to which the channel is buried in the buried region 6 in the Example is greater than in the Comparative Example. The reason for this is that the buried region 6 according to the Example includes the p-type first region 7 and the n-type second region 8, unlike the Comparative Example in which all portions of the buried region are p-type. In other words, the position of the n-type second region 8 above the p-type first region 7 changes the energy level of the valence electrons in the buried region 6 in the Example. This change in the valence band energy level in the Example makes the energy barrier between the peak position of the valence band energy and the interface between the gate insulating film 15 and the buried region 6 larger than in the Comparative Example. As a result of the larger energy barrier between the interface between the gate insulating film 15 and the buried region 6, the degree to which the channel is buried in the buried region 6 in the Example is greater than in the Comparative Example.

### <Result 5>

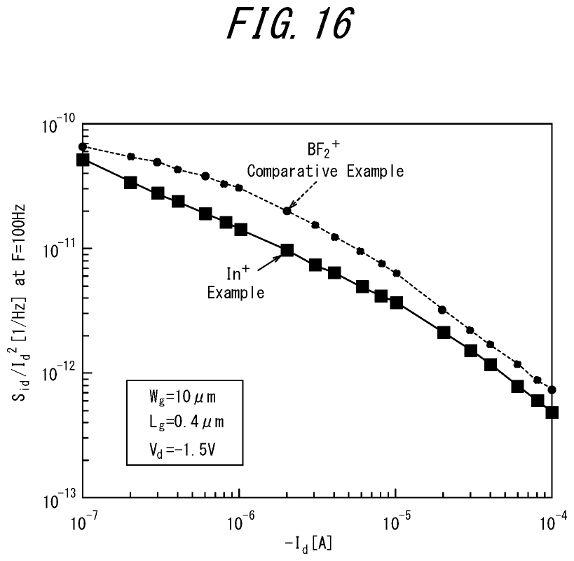

FIG. 16 is a diagram illustrating the results of actual measurement of 1/f noise. The horizontal axis is the drain current (−I_{d} [A]). The vertical axis indicates the normalized drain current equivalent noise. The normalized drain current equivalent noise is the drain current equivalent noise (Sid) divided by the square of the drain current (I_{d}²). The frequency f is 100 Hz.

The square plot indicates an Example. In other words, the Example is a transistor 4 formed by counter ion implantation of indium ions (In⁺).

The circle plot indicates a Comparative Example. The Comparative Example is a transistor formed by counter ion implantation of boron bifluoride ions (BF₂⁺), as in Result 4.

The overall 1/f noise was reduced in the Example as compared to the Comparative Example. In particular, the difference in 1/f noise between the Example and the Comparative Example increased when the drain current (−I_{d}[A]) reached approximately 1 μA. This is because the transistor according to the Comparative Example behaves like a surface channel transistor when the drain current reaches approximately −1 μA, as described above with reference to FIG. 15.

As described above, in the transistor 4 according to the first embodiment, the burying depth of the first region 7 in the well region 5 from the surface of the semiconductor substrate 2 is 50 nm or more. With this configuration, the effect of the interface between the gate insulating film 15 and the buried region 6 on the channel formed in the buried region 6 can be smaller than the case in which the burying depth of the first region 7 in the well region 5 is less than 50 nm. By reducing the effect of the interface on the channel, the 1/f noise in the transistor 4 can be reduced.

Here, as described above, if the region where the channel is formed is deeply buried in the semiconductor substrate in a conventional transistor, the short-channel effect increases. Therefore, in the buried channel transistor described above in PTL 1, the depth of the region where the channel is formed was 0.05 μm or less.

In contrast, the transistor 4 according to the first embodiment is provided with the buried region 6 including the p-type first region 7 and the n-type second region 8. By the n-type second region 8 thus being included in the buried region 6, the p-type impurity concentration near the interface between the buried region 6 and the gate insulating film 15 in the transistor 4 is lower than in conventional transistors in which the buried region does not include an n-type region. Hence, in the transistor 4, the p-type impurity concentration near the interface between the buried region 6 and the gate insulating film 15 is reduced, and unlike conventional transistors, a reduction in the voltage threshold of the transistor can be suppressed. As a result, the transistor 4 can suppress an increase in off-leakage current. The transistor 4 according to the first embodiment can therefore suppress an increase in the short-channel effect even when the burying depth of the first region 7 in the well region 5 is 50 nm or more.

Furthermore, in the transistor 4 according to the first embodiment, the buried region 6 includes the p-type first region 7 and the n-type second region 8, thereby increasing the degree to which the channel is buried in the buried region 6, as described above with reference to FIG. 15. Since the degree to which the channel is buried in the buried region 6 is increased in the transistor 4, the 1/f noise can be reduced even when the drain current is approximately—1 μA, as described above with reference to FIG. 15.

According to the present disclosure, a semiconductor apparatus and a method for manufacturing a semiconductor apparatus in which an increase in the short-channel effect is suppressed while 1/f noise is reduced can thus be provided.

### Second Embodiment

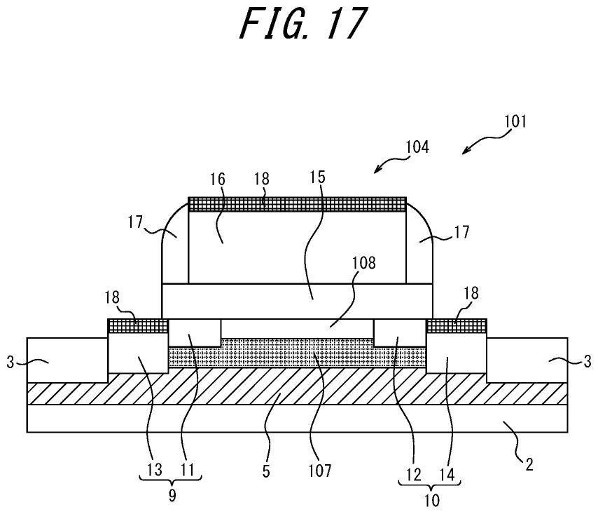

As illustrated in FIG. 17, a semiconductor apparatus 101 according to a second embodiment of the present disclosure includes a semiconductor substrate 2, an element separation layer 3, and a transistor 104.

The transistor 104 is located on the surface layer of the semiconductor substrate 2. The transistor 104 is a MOSFET. The transistor 104 is a p-type buried channel transistor. The transistor 104 may, however, instead be an n-type buried channel transistor.

In the present embodiment, the first conductivity type is n-type. The second conductivity type is p-type. In a case in which the transistor 104 is an n-type buried channel transistor, however, the first conductivity type may be p-type and the second conductivity type may be n-type.

The transistor 104 includes a well region 5, a source region 9, a drain region 10, a gate insulating film 15, a gate electrode 16, a sidewall 17, and a silicide layer 18. The transistor 104 further includes a first region 107 and a second region 108.

The first region 107 is p-type. The first region 107 contains a p-type impurity. The first region 107 contains boron, for example. The first region 107 is located between the source region 9 and the drain region 10. The first region 107 is buried in the well region 5. The burying depth of the first region 107 in the well region 5 from the surface of the semiconductor substrate 2 is 50 nm or more. As described below, the first region 107 is formed by counter ion implantation of p-type impurity ions into the well region 5. The p-type impurity ions are, for example, boron bifluoride ions (BF₂⁺).

The second region 108 is n-type. The second region 108 contains an n-type impurity. The second region 108 contains phosphorus, for example. The thickness of the second region 108 is, for example, 10 nm to 50 nm.

The second region 108 is located between the first region 107 and the gate insulating film 15. The second region 108 is located above the semiconductor substrate 2. The second region 108 is, for example, a silicon thin film.

### <Method of Manufacturing a Semiconductor Apparatus>

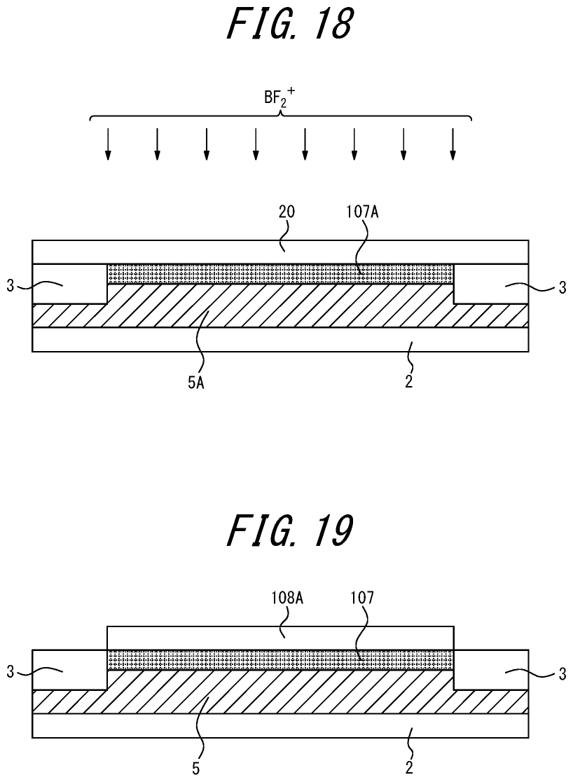

Next, a method of manufacturing the semiconductor apparatus 101 illustrated in FIG. 17 will be described with reference to FIGS. 18 to 20. By modifying the method of manufacturing described below as appropriate, a semiconductor apparatus 101 provided with an n-type buried channel transistor instead of or in addition to the transistor 104 may be manufactured.

First, the semiconductor substrate 2 is prepared. Next, as described above with reference to FIG. 2, the element separation layer 3 is formed on the surface layer of the semiconductor substrate 2. A through film 20 is subsequently formed on the semiconductor substrate 2 in the same or similar manner as in the first embodiment. Next, phosphorus ions (P⁺), which are n-type impurity ions, are selectively implanted in the surface layer of the semiconductor substrate 2 through the through film 20, as described above with reference to FIG. 3.

Next, counter ion implantation is performed as illustrated in FIG. 18. In the present embodiment, boron bifluoride ions (BF₂⁺), which are p-type impurity ions, are selectively implanted in the well region 5A through the through film 20. The use of boron bifluoride ions (BF₂⁺) solves the problem of kinks appearing in the drain current-gate voltage characteristics (I_{d}-V_{g} characteristics) in the transistor 104. Also, the use of boron bifluoride ions (BF₂⁺) can lower the voltage threshold of the transistor 104. The implantation of boron bifluoride ions (BF₂⁺) is, for example, performed under the conditions of an acceleration voltage of 40 keV to 100 keV and a dose of 3×10¹² to 1×10¹³ cm⁻². Such counter ion implantation forms a first region 107A, which later becomes the first region 107.

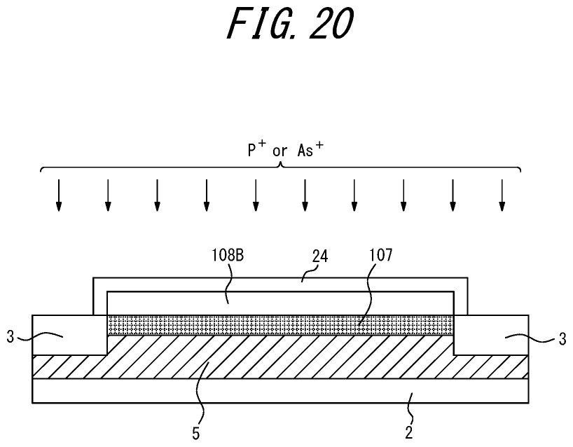

After counter ion implantation is performed, activation annealing is performed. To suppress the diffusion of boron in the semiconductor substrate 2, the conditions for activation annealing may be a temperature of 930° C. to 1000° C. and a duration of 120 seconds or less. The activation annealing activates the impurity ions in the well region 5A and the first region 107A. The activation of the impurity ions forms the n-type well region 5 and the p-type first region 107, as illustrated in FIG. 19.

Next, after the through film 20 is removed, a non-doped silicon thin film 108A is formed on the surface of the first region 107, as illustrated in FIG. 19. The silicon thin film 108A may be formed by epitaxial growth. The thickness of the silicon thin film 108A is, for example, 10 nm to 50 nm.

Next, a through film 24 is formed, as illustrated in FIG. 20. The through film 24 is, for example, a silicon oxide (SiO₂) film. The thickness of the through film 24 is, for example, 20 nm or less. Subsequently, ion implantation of phosphorus ions (P⁺) or arsenic ions (As⁺) into the silicon thin film 108A through the through film 24 is performed. The ion implantation of phosphorus ions (P⁺) or arsenic ions (As⁺) into the silicon thin film 108A forms a silicon thin film 108B. The ion implantation of phosphorus ions (P⁺) or arsenic ions (As⁺) is, for example, performed under the conditions of an acceleration voltage of 5 keV to 7 keV and a dose in a range of 3×10¹¹ cm⁻² to 3×10¹² cm⁻².

Here, instead of the non-doped silicon thin film 108A as illustrated in FIG. 19, a silicon thin film doped with an n-type impurity may be formed on the surface of the first region 107. The silicon thin film doped with an n-type impurity may be formed by epitaxial growth.

Next, activation annealing is performed. The activation annealing activates the impurity ions in the silicon thin film 108B. The activation of the impurity ions in the silicon thin film 108B forms the second region 108 as illustrated in FIG. 17.

Subsequently, the source region 9, the drain region 10, the gate insulating film 15, the gate electrode 16, the sidewall 17, and the silicide layer 18 are formed by the processes described above with reference to FIGS. 5 to 11. However, the extension regions 11, 12 may be formed in the second region 108 or in the semiconductor substrate 2, depending on the conditions for extension ion implantation. The conditions for high temperature lamp annealing performed after formation of the insulating film 15A and polysilicon film 16A are a temperature of 965° C. or more and 1050° C. or less and a time of 15 seconds or more and 30 seconds or less. This high temperature lamp annealing is performed by the RTA method.

### <Result 1>

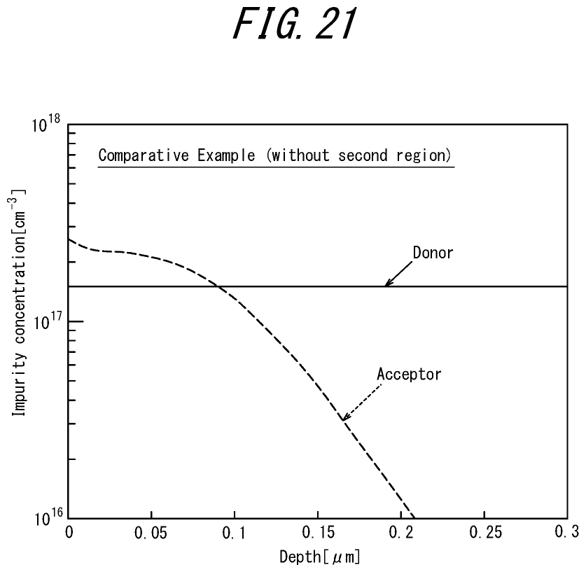

FIG. 21 is a diagram illustrating the results of simulating an impurity distribution according to a Comparative Example. The transistor according to the Comparative Example does not include the second region 108. In FIG. 21, the horizontal axis indicates the depth [μm] in the semiconductor substrate. The 0 [μm] on the horizontal axis corresponds to the interface between the gate oxide film and the semiconductor substrate. The vertical axis indicates the impurity concentration [cm⁻³].

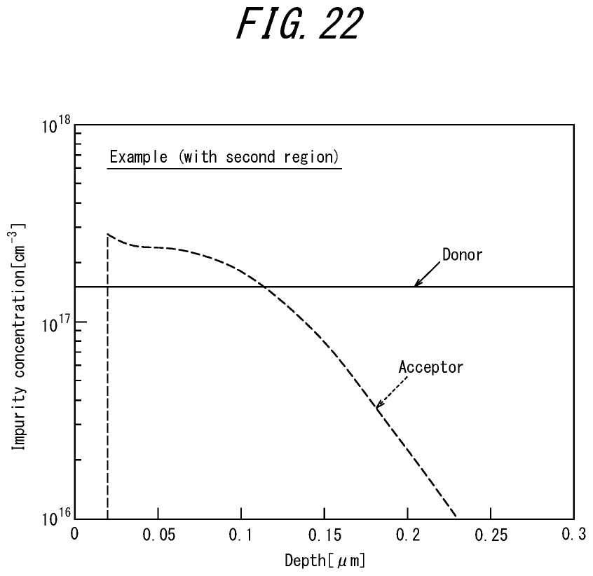

FIG. 22 is a diagram illustrating the results of simulating an impurity distribution according to an Example. That is, FIG. 22 illustrates the result of simulating the impurity distribution in the transistor 104 including the second region 108. In FIG. 22, the horizontal axis indicates the depth [μm] in the second region 108 or the semiconductor substrate 2. The 0 [μm] on the horizontal axis corresponds to the interface between the gate oxide film and the second region 108. The vertical axis indicates the impurity concentration [cm⁻¹].

In FIGS. 21 and 22, the solid line indicates the donor concentration. The dashed line indicates the acceptor concentration. In the Example, the donor concentration in the second region 108 and the donor concentration in the well region 5 are the same.

As illustrated in FIG. 21, in the Comparative Example, the acceptor concentration is higher than the donor concentration when the depth in the semiconductor substrate is in a range of 0 μm to 0.09 μm. In other words, the semiconductor substrate becomes p-type at depths in a range of 0 μm to 0.09 μm. In a range in which the depth in the semiconductor substrate is greater than 0.09 μm, the donor concentration is higher than the acceptor concentration. In other words, the semiconductor substrate becomes n-type at depths in a range deeper than 0.09 μm.

In the Example illustrated in FIG. 22, a range of depths from 0 μm to 0.02 μm corresponds to a depth in the second region 108. Therefore, when the depth is in a range of 0 μm to 0.02 μm, the acceptor concentration is zero. In other words, a range in which the depth is 0 μm to 0.02 μm is n-type. A range in which the depth is greater than 0.02 μm corresponds to a depth in the semiconductor substrate 2. In a range in which the depth is 0.02 μm to 0.12 μm, the acceptor concentration is higher than the donor concentration. In other words, a range of depths from 0.02 μm to 0.12 μm is p-type and corresponds to the first region 107. In a range in which the depth is greater than 0.12 μm, the donor concentration is higher than the acceptor concentration. In other words, a range in which the depth is greater than 0.12 μm is n-type.

### <Result 2>

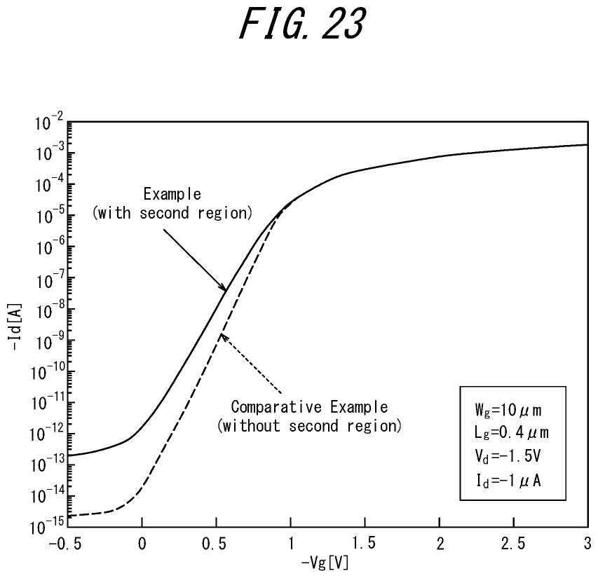

FIG. 23 is a diagram illustrating the results of simulation of drain current-gate voltage characteristics (I_{d}-V_{g} characteristics). The gate width (W_{g}) of the transistor used in the simulation was 10 μm, and the gate length (L_{g}) of the transistor was 0.4 μm. The drain voltage (V_{d}) was set to −1.5 V in the simulation.

In FIG. 23, the horizontal axis indicates the gate voltage (−V_{g} [V]). The vertical axis indicates the drain current (−I_{d} [A]).

The solid line indicates an Example. That is, the solid line indicates the drain current-gate voltage characteristics of the transistor 104 provided with the second region 108.

The dashed line indicates the drain current-gate voltage characteristics of a transistor without the second region as a Comparative Example.

The subthreshold characteristics were worse in the Example than in the Comparative Example. This is because the transistor 104 in the Example is provided with the second region 108, and hence the degree to which the channel is buried in the semiconductor substrate 2 is greater in the Example than in the Comparative Example. However, the Example and the Comparative Example exhibited nearly the same characteristics in a region in which |V_{g}|≥|Vₜₕ| (where V_{g} is the gate voltage and Vₜₕ is the threshold voltage).

No kink appeared in the I_{d}-V_{g} characteristics in the transistor of both the Example and the Comparative Example. This was due to the use of boron bifluoride ions (BF₂⁺) for counter ion implantation.

### <Result 3>

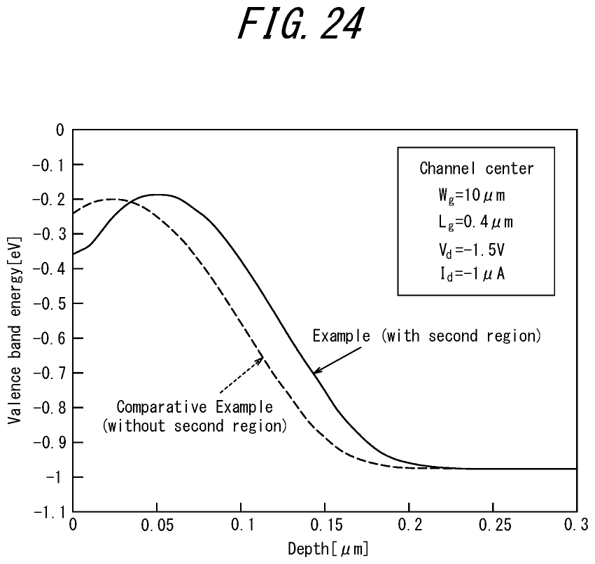

FIG. 24 is a diagram illustrating the results of simulating valence bands. The horizontal axis indicates the depth [μm] in the semiconductor substrate. The 0 [μm] on the horizontal axis corresponds to the surface of the semiconductor substrate in the Comparative Example and the surface of the second region 108 in the Example. The vertical axis indicates the valence band energy [eV].

In this simulation, the gate width of the transistor (W_{g}) was set to 10 μm and the gate length of the transistor (L_{g}) was set to 0.4 μm in both the Example and the Comparative Example. The drain voltage (V_{d}) of the transistor was set to −1.5 V and the drain current (I_{d}) of the transistor was set to −1 μA. FIG. 24 illustrates the valence band energy in the center of the channel formed between the source region and the drain region of the transistor.

The solid line indicates the Example. That is, the solid line indicates the valence band energy of the channel in the transistor 104 provided with the second region 108. In the Example, the burying depth of the first region 107 in the well region 5 from the surface of the semiconductor substrate 2 was 50 nm or more.

The dashed line indicates the valence band energy of the channel in a transistor without the second region as a Comparative Example. Except for not being provided with the second region, the configuration of the transistor according to the Comparative Example is the same as that of the transistor according to the Example.

As can be seen from the dashed line, the peak of the valence band energy in the Comparative Example was near a depth of 0 μm in the semiconductor substrate, i.e., near the interface. It can be seen from this result that when the drain current reaches approximately −1 μA in the Comparative Example, the channel ends up flowing through the interface between the gate insulating film and the p-type buried region. In other words, despite being a buried channel transistor, the transistor according to the Comparative Example behaves like a surface channel transistor when the drain current becomes approximately −1 μA. Thus, in the transistor according to the Comparative Example, when the drain current becomes approximately −1 μA, the channel ends up flowing through the interface between the gate insulating film and the p-type buried region, resulting in a large 1/f noise.

As can be seen from the solid line, the peak of the valence band energy in the Example was near a depth of 0.05 μm in the semiconductor substrate 2. In other words, in the Example, a channel is formed near a depth of 0.05 μm in the semiconductor substrate 2 even when the drain current becomes approximately −1 μA. That is, unlike the Comparative Example, the channel is buried in the semiconductor substrate 2 in the transistor 104 according to the Example even when the drain current becomes approximately −1 μA. Since the channel is thus buried in the semiconductor substrate 2 in the transistor 104 according to the Example even when the drain current becomes approximately −1 μA, the 1/f noise can be reduced.

It is thus clear that the degree to which the channel is buried in the first region 107 in the Example is greater than in the Comparative Example. The reason for this is that the n-type second region 108 is located above the p-type first region 107, as described above with reference to FIG. 15.

Other configurations and effects of the semiconductor apparatus 101 according to the second embodiment are the same or similar to those of the semiconductor apparatus 1 according to the first embodiment.

Although an embodiment of the present disclosure has been described based on the various drawings and examples, it should be noted that a person of ordinary skill in the art could easily make various modifications and revisions based on the present disclosure. Accordingly, such modifications and revisions should also be considered to be included within the scope of the present disclosure. For example, functions and the like included in various constituent parts, etc., may be rearranged so long as they are logically consistent. Moreover, a plurality of constituent parts, etc., may be combined as a single part or may be split up.

1. A semiconductor apparatus comprising:
a gate insulating film;
a well region of a first conductivity type located on a surface layer of a semiconductor substrate;
a source region of a second conductivity type and a drain region of the second conductivity type located on a surface layer of the well region;
a first region of the second conductivity type located between the source region and the drain region and buried in the well region; and
a second region of the first conductivity type located between the first region and the gate insulating film, wherein
a burying depth of the first region in the well region from a surface of the semiconductor substrate is 50 nm or more.

2. The semiconductor apparatus according to claim 1, wherein
the well region contains an impurity of the first conductivity type,
the first region and the second region contain an identical type of impurity of the second conductivity type,
a concentration of the impurity of the second conductivity type contained in the first region is higher than a concentration of the impurity of the first conductivity type contained in the well region,
a concentration of the impurity of the second conductivity type contained in the second region is lower than the concentration of the impurity of the first conductivity type contained in the well region, and
the concentration of the impurity of the first conductivity type is in a range of 1×10¹⁶ cm⁻³ or more to 1×10¹⁸ cm⁻³ or less.

3. The semiconductor apparatus according to claim 2, wherein the impurity of the second conductivity type is indium.

4. The semiconductor apparatus according to claim 2, wherein the second region is buried in the well region together with the first region.

5. The semiconductor apparatus according to claim 4, wherein a burying depth of the second region in the well region from the surface of the semiconductor substrate is 1 nm or more and 50 nm or less.

6. The semiconductor apparatus according to claim 1, wherein
the second region is a silicon thin film, and
the second region is located above the semiconductor substrate.

7. The semiconductor apparatus according to claim 6, wherein the first region contains boron as an impurity of the second conductivity type.

8. The semiconductor apparatus according to claim 6, wherein a thickness of the second region is 10 nm or more and 50 nm or less.

9. The semiconductor apparatus according to claim 1, wherein an interface state density between the gate insulating film and the semiconductor substrate is 1.0×10¹⁰ cm⁻² or less.

10. The semiconductor apparatus according to claim 9, wherein the interface state density between the gate insulating film and the semiconductor substrate is 1.0×10⁹ cm⁻² or more and 1.0×10¹⁰ cm⁻² or less.

11. A method of manufacturing the semiconductor apparatus according to claim 2, the method comprising:
performing counter ion implantation of impurity ions of the second conductivity type in the semiconductor substrate so that the concentration of the impurity of the second conductivity type on the gate insulating film side in the well region is lower than the concentration of the impurity of the first conductivity type in the well region, wherein
the impurity of the second conductivity type exhibits a retrograde distribution.

12. The method of manufacturing the semiconductor apparatus according to claim 11, further comprising
performing high temperature lamp annealing after forming an insulating film that becomes the gate insulating film and a polysilicon film that becomes a gate electrode, wherein
the high temperature lamp annealing is performed under conditions of a temperature of 965° C. or more and 1125° C. or less and a time of 15 seconds or more and 60 seconds or less.

13. A method of manufacturing the semiconductor apparatus according to claim 6, the method comprising:
performing counter ion implantation of impurity ions of the second conductivity type in the semiconductor substrate;
forming a silicon thin film on the semiconductor substrate by epitaxial growth; and
performing ion implantation of impurity ions of the first conductivity type in the silicon thin film.

14. The method of manufacturing the semiconductor apparatus according to claim 13, further comprising
performing high temperature lamp annealing after forming an insulating film that becomes the gate insulating film and a polysilicon film that becomes a gate electrode, wherein
the high temperature lamp annealing is performed under conditions of a temperature of 965° C. or more and 1050° C. or less and a time of 15 seconds or more and 30 seconds or less.

15. A method of manufacturing the semiconductor apparatus according to claim 6, the method comprising:
performing counter ion implantation of impurity ions of the second conductivity type in the semiconductor substrate; and
forming a silicon thin film doped with an impurity of the first conductivity type on the semiconductor substrate by epitaxial growth.

16. The method of manufacturing the semiconductor apparatus according to claim 15, further comprising
performing high temperature lamp annealing after forming an insulating film that becomes the gate insulating film and a polysilicon film that becomes a gate electrode, wherein
the high temperature lamp annealing is performed under conditions of a temperature of 965° C. or more and 1050° C. or less and a time of 15 seconds or more and 30 seconds or less.
